(19) United States
(12) Patent Application Publication
(10) Pub. No.: US 2012/0150461 A1
(43) Pub. Date: Jun. 14, 2012

(54) ELECTRIC POWER MEASURING DEVICE, METHOD FOR MEASURING ELECTRIC POWER, ELECTRIC POWER MEASURING SYSTEM, INFORMATION-PROCESSING DEVICE, CONTROL PROGRAM, AND STORAGE MEDIUM

(76) Inventors: Kohji OHIWA, Osaka (JP); Shinya Ito, Osaka (JP)

(21) Appl. No.: 13/205,806

(22) Filed: Aug. 9, 2011

(30) Foreign Application Priority Data
Dec. 10, 2010 (JP) 2010-276045

(51) Int. Cl. G01R 21/00; G01R 35/00; G06F 19/00

(52) U.S. Cl. 702/60

(57) ABSTRACT

The electric power measuring device includes (i) a plug which is to be connected to a power supply outlet, (ii) a socket to which a load is connected so that electric power is supplied from the plug to the load, (iii) an electric power measuring section for measuring the electric power consumed by the load, (iv) a memory section for storing measurement error information regarding the electric power measuring section, and (v) a correcting section for correcting, based on the measurement error information, a value of electric power measured by the electric power measuring section.

This Nonprovisional application claims priority under 35 U.S.C. §119(a) on Patent Application No. 2010-276045 filed in Japan on Dec. 10, 2010, the entire contents of which are hereby incorporated by reference.

### TECHNICAL FIELD

The present invention relates mainly to an electric power measuring device which measures power consumption of a device, such as a household appliance in a home or an office appliance in an office.

### BACKGROUND ART

In these years, there has been more interest in energy saving in view of environmental issues. This has led to an increase in demands for checking power consumption not only in a company but also in each house.

Recently, a household appliance such as an air conditioner, which has a function to display its power consumption, has been released. However, such a household appliance is expensive and cannot measure power consumption of another household appliance. Therefore, most household appliances cannot measure power consumption.

In order to check power consumption of most of household appliances and office appliances (hereinafter, collectively referred to as electric equipment), it is necessary to provide an electric power measuring device for each power outlet. In view of this, the electric power measuring device needs to be (i) configured by low-cost parts and (ii) manufactured at low cost.

In general, power consumption of each house is measured by a power meter provided by the electric power company, and monthly electricity bill is charged based on the measured result. The bill statement accurately describes electric energy consumed by the house. Therefore, the electric power measuring device is required to carry out a highly accurate measuring.

Patent Literatures 1 and 2 disclose a configuration in which an electric power measuring device is provided between a power supply outlet and electric equipment, whose electric power is to be measured, and the electric power consumed by the electric equipment is measured. The electric power information is sent to, for example, a server, and the electric power information is stored in the server. The electric power information can be checked via the server at any time. Such an electric power measuring device includes a sensor section which is configured by an IC. The sensor section measures a voltage and a current of the electric equipment, whose electric power is to be measured, and the electric power is calculated based on the measured voltage and current.

Measuring accuracy of such an electric power measuring device would be deteriorated due to the following factors (1) through (5):

(1) Accuracy in measuring voltage by the sensor section
(2) Accuracy in measuring current by the sensor section
(3) Reference voltage of sensor section
(4) Measured value shift caused by temperature
(5) Accuracy of measuring frequency

It is confirmed that the factor (4) can be ignored because (i) the measured values can be automatically corrected in accordance with ambient temperature, which is measured by a temperature sensor provided in the sensor section, and (ii) the factor (4) itself affects the measuring accuracy less than the other factors (1) through (3), and (5), that is, an actual effect caused by the factor (4) is within 1% even under a condition beyond an operating temperature range (e.g., a condition in a range between −5° C. and +70° C.).

With regard to the factor (5), it is confirmed that an effect caused by the factor (5) can be reduced, by the use of a crystal having an accuracy of ±10 ppm or less, such that the measured values do not need to be corrected.

Moreover, the factors (1) through (3) are all related to initial value correction. The factor (1) depends on individual accuracy of each sensor section, and an actual error is approximately ±5%. The factor (2) depends on unevenness in resistance of a shunt resistor, in addition to on individual accuracy of each sensor section, and an actual error is approximately 5%. The factor (3) also depends on individual accuracy of each sensor section itself.

In view of this, only the factors (1) through (3) need to be considered for improving accuracy in measuring electric power. The factors (1) through (3) cause an error of more than ±10%. However, the error is caused by individual accuracy of each sensor section and unevenness in resistance of the shunt resistor. The error can be therefore reduced close to zero by appropriately calibrating setting of the electric power measuring device while manufacturing.

Specifically, power consumption is calculated as electric power information by comparing the measured values of the factors (1) and (2) with the reference voltage of the factor (3). It is therefore possible to reduce the error, which is caused by the factors (1) through (3), close to zero by calibrating any one of the measured voltage, the measured current, and the reference voltage, while manufacturing.

According to a conventional electric power measuring device, the error is reduced close to zero by the use of a calibration circuit 200 which is provided in the conventional electric power measuring device (see FIG. 7). The calibration circuit 200 is incorporated in a voltage measuring circuit of a sensor section, and calibrates, while taking account of an error in measuring current and an error of a reference voltage, an error in measuring electric power.

Specifically, highly accurate electric equipment is connected to a socket section of the electric power measuring device so that the electric equipment consumes certain electric power. Resistance of the entire calibration circuit 200 is adjusted so that appropriate electric power information can be supplied at the time. This causes a voltage, which is applied to the voltage measuring circuit, to be adjusted, and therefore an error in measuring the electric power is calibrated (i.e., the error is reduced close to zero).

Note that the calibration circuit 200 is configured by a resistor network (see FIG. 7). According to the configuration, an output voltage V2out of the voltage measuring circuit is adjusted by turning on/off switches S1 through S5, which are connected in series with respective resistors A through E, so that an error in measuring electric power is reduced to zero.

### CITATION LIST

### Patent Literature

### Patent Literature 1

Japanese Patent Application Publication, Tokukai, No. 2010-230330 (Publication Date: Oct. 14, 2010)

### Patent Literature 2

Japanese Patent Application Publication, Tokukaihei, No. 8-184616 (Publication Date: Jul. 16, 1996)

### SUMMARY OF INVENTION

### Technical Problem

However, each of the switches S1 through S5 of the calibration circuit 200 is generally configured by a patterned land in actual use in view of cost reduction, and is turned on/off by opening/short-circuiting the patterned land. Moreover, it is not appropriate to use a variable resistor as each of the switches S1 through S5 instead, in view of reliability and long-term stability (i.e., a value is shifted in the long term).

The accuracy in measuring electric power by the calibration circuit 200 can be improved by increasing the number of resistors and switches. However, such an increase of the number of resistors and switches leads to an increase in (i) parts cost and (ii) manufacturing cost because time, which is required for turning on/off the switches (i.e., for short-circuiting the switches by soldering), increases.

The present invention is accomplished in view of the problem, and its object is to provide an electric power measuring device, a method for measuring electric power, an electric power measuring system, an information-processing device, a control program, and a storage medium, which can reduce parts cost and manufacturing cost without deteriorating accuracy in measuring electric power.

### Solution to Problem

In order to attain the object, an electric power measuring device of the present invention includes: a plug which is to be connected to a power supply outlet; a socket to which a load is connected so that electric power is supplied from the plug to the load; electric power measuring means for measuring the electric power which is supplied to the load; memory means for storing measurement error information regarding the electric power measuring means; and correcting means for correcting, based on the measurement error information, a value of electric power measured by the electric power measuring means.

According to the configuration, the memory means stores the measurement error information, and the correcting means corrects, based on the measurement error information, the value of electric power measured by the electric power measuring means. That is, the value of measured electric power is corrected by the use of a software-based method instead of using a conventional hardware-based method. This makes it possible to reduce parts cost and manufacturing cost without deteriorating accuracy in measuring electric power.

An electric power measuring device of the present invention includes: a plug which is to be connected to a power supply outlet; a socket to which a load is connected so that electric power is supplied from the plug to the load; electric power measuring means for measuring the electric power which is supplied to the load; first communication means for receiving measurement error information, which is sent from a predetermined information-processing device, regarding the electric power measuring means; and correcting means for correcting, based on the measurement error information, a value of electric power measured by the electric power measuring means.

According to the configuration, the first communication means receives the measurement error information sent from the predetermined information-processing device, and the correcting means corrects, based on the measurement error information, the valued of electric power measured by the electric power measuring means. That is, the value of measured electric power is corrected by the use of a software-based method instead of using a conventional hardware-based method. This makes it possible to reduce parts cost and manufacturing cost without deteriorating accuracy in measuring electric power.

Moreover, the measurement error information is sent from the predetermined information-processing device to the first communication means (i.e., the measurement error information is not stored in the electric power measuring device). This makes it possible to reduce memory capacity for storing measurement error information in the electric power measuring device, and therefore parts cost of the electric power measuring device can be reduced.

An electric power measuring system of the present invention includes: an electric power measuring device which measures electric power which is consumed by a load; and an information-processing device which can communicate with the electric power measuring device, the electric power measuring device including: a plug which is to be connected to a power supply outlet, a socket to which the load is connected so that electric power is supplied from the plug to the load, electric power measuring means for measuring the electric power which is supplied to the load, and first communication means for sending, to the information-processing device, a value of electric power measured by the electric power measuring means and identification information of the electric power measuring device, the information-processing device including: first memory means for storing (i) measurement error information regarding the electric power measuring means and (ii) identification information of the electric power measuring device so that the measurement error information and the identification information are associated with each other, second communication means for receiving the value of measured electric power and the identification information which are sent via the first communication means, selecting means for selecting the measurement error information which is associated with the identification information received via the second communication means, and correcting means for correcting, based on the measurement error information selected by the selecting means, the value of measured electric power received via the second communication means.

According to the configuration, in the electric power measuring device, the first communication means sends the value of electric power measured by the electric power measuring means to the information-processing device. In the information-processing device, the measurement error information is stored in the first memory means, and the correcting means corrects, based on the measurement error information, the value of electric power measured by the electric power measuring means. That is, the value of measured electric power is corrected by the use of a software-based method instead of using a conventional hardware-based method. This makes it possible to reduce parts cost and manufacturing cost without deteriorating accuracy in measuring electric power.

Moreover, the measurement error information is stored in the first memory means of the information-processing device (i.e., the measurement error information is not stored in the electric power measuring device). This makes it possible to reduce memory capacity for storing measurement error information in the electric power measuring device, and therefore cost of the electric power measuring device can be reduced.

Moreover, in the electric power measuring device, the first communication means sends the value of measured electric power and the identification information to the information-processing device. In the information-processing device, the measurement error information and the identification information are stored in the first memory means so as to be associated with each other, and the correcting means corrects the value of measured electric power, which is sent from the electric power measuring device, with the use of the measurement error information associated with the identification information sent from the electric power measuring device. This allows values of electric power, which are measured by respective of a plurality of electric power measuring devices, to be corrected without confusion.

Moreover, a value of measured electric power is corrected in the information-processing device, and therefore a processing load on the electric power measuring device can be reduced.

An information-processing device of the present invention includes: memory means for storing (i) measurement error information regarding a predetermined electric power measuring device and (ii) identification information of the predetermined electric power measuring device so that the measurement error information and the identification information are associated with each other; communication means for receiving, from the predetermined electric power measuring device, a value of measured electric power and identification information; selecting means for selecting the measurement error information which is associated with the identification information received via the communication means; and correcting means for correcting, based on the measurement error information selected by the selecting means, the value of measured electric power received via the communication means.

According to the configuration, in the information-processing device, the memory means stores the measurement error information, and the correcting means corrects, based on the measurement error information, the value of electric power measured by the electric power measuring means. That is, the value of measured electric power is corrected by the use of a software-based method instead of using a conventional hardware-based method. This makes it possible to reduce parts cost and manufacturing cost without deteriorating accuracy in measuring electric power.

### Advantageous Effects of Invention

As described above, the electric power measuring device of the present invention includes a plug which is to be connected to a power supply outlet; a socket to which a load is connected so that electric power is supplied from the plug to the load; electric power measuring means for measuring the electric power which is supplied to the load; memory means for storing measurement error information regarding the electric power measuring means; and correcting means for correcting, based on the measurement error information, a value of electric power measured by the electric power measuring means.

This brings about an effect of reducing parts cost and manufacturing cost without deteriorating accuracy in measuring electric power.

### BRIEF DESCRIPTION OF DRAWINGS

FIG. 1 is a schematic view illustrating a configuration of an electric power measuring device in accordance with Embodiment 1 of the present invention.

FIG. 2 is a view illustrating an example of an appearance of the electric power measuring device in accordance with Embodiment 1 of the present invention.

FIG. 3 is a schematic view illustrating a configuration of an electric power measuring system in accordance with Embodiment 2 of the present invention.

FIG. 4 is a schematic view illustrating a configuration of an electric power measuring system in accordance with Embodiment 3 of the present invention.

FIG. 5 is a schematic view illustrating a configuration of an electric power measuring system in accordance with Embodiment 4 of the present invention.

FIG. 6 is a schematic view illustrating a configuration of an electric power measuring system in accordance with Embodiment 5 of the present invention.

FIG. 7 is a view illustrating an example of a calibration circuit.

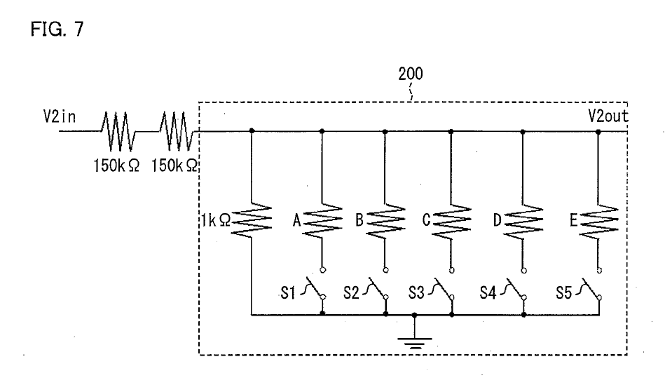

### DESCRIPTION OF EMBODIMENTS

### Embodiment 1

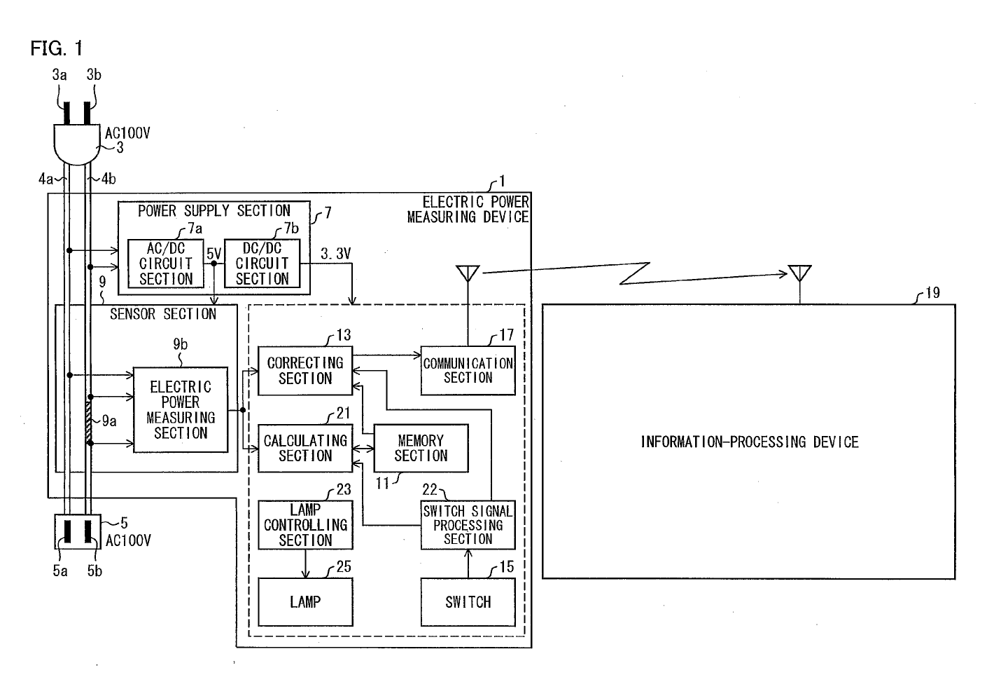

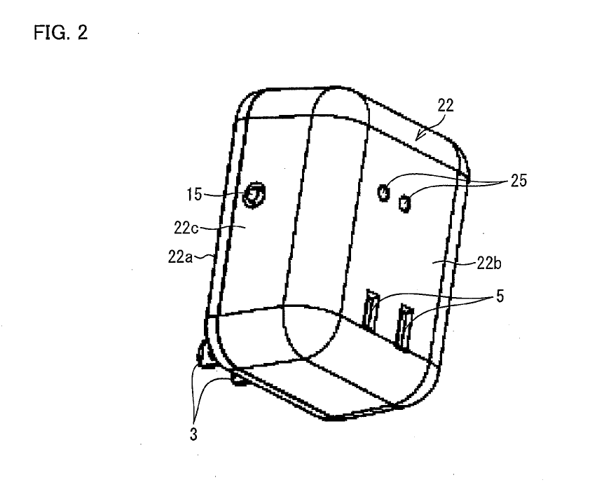

The following describes Embodiment 1 of the present invention with reference to FIGS. 1 and 2. First, an outline of an electric power measuring device 1 of the present embodiment is described with reference to FIGS. 1 and 2.

### (Outline of Electric Power Measuring Device 1)

The electric power measuring device 1 of the present embodiment is provided between a power supply outlet and a load (e.g., electric equipment such as a household appliance or an office appliance) so as to measure electric power which has been consumed by the load. The electric power measuring device 1 includes a plug 3, a socket 5, a power supply section 7, a sensor section 9, a memory section 11 (memory means), a correcting section 13 (correcting means), a switch 15 (operation accepting means), a communication section 17 (communication means), a calculating section 21 (calculating means), a switch signal processing section 22, a lamp controlling section 23, and a lamp 25 such as an LED (see FIG. 1).

The electric power measuring device 1 includes a hollow housing 22 which has, for example, a substantially cubic shape (see FIG. 2). The sections 7, 9, 11, 13, 17, 21, 22, and 23 are housed in the housing 22. The plug 3 is provided so as to project from a back surface 22a of the housing 22. The socket 5 and, for example, two lamps 25 are provided on a surface 22b which is opposite to the back surface 22a. The switch 15 is provided on a side surface 22c of the housing 22.

The plug 3 is configured so as to be connected to or disconnected from a predetermined power supply outlet (not illustrated). A power supply plug of a load (not illustrated), whose electric power is to be measured, is to be connected to or disconnected from the socket 5. One male terminal 3a of the plug 3 is connected with one female terminal 5a of the socket 5 via a wire 4a. The other male terminal 3b of the plug 3 is connected with the other female terminal 5b of the socket 5 via a wire 4b.

With the configuration, when (i) the plug 3 is connected to the power supply outlet and (ii) the load is connected to the socket 5, electric power is supplied to the load from the power supply outlet, via the plug 3, the wires 4a and 4b, and the socket 5.

The power supply section 7 causes the electric power to be supplied from the plug 3 to the sections 9, 11, 13, 15, 17, 21, 22, 23, and 25. Specifically, the power supply section 7 (i) receives an AC voltage (e.g., 100 V) supplied via the plug 3 and (ii) converts the AC voltage into DC voltages which are necessary for the sections so as to supply the DC voltages to the sections. For example, the power supply section 7 includes (i) an AC/DC circuit section 7a which converts the AC voltage supplied via the plug 3 into a DC voltage (e.g., 5 V) at which the sensor section 9 is operated and (ii) a DC/DC circuit section 7b which converts the DC voltage into a DC voltage (e.g., 3.3 V) at which each of the sections 11, 13, 15, 17, 21, 22, 23, and 25 is operated.

For example, when the plug 3 is connected to the power supply outlet, electric power starts to be automatically supplied from the power supply section 7 to the sections 9, 11, 13, 15, 17, 21, 22, 23, and 25. This causes the electric power measuring device 1 to be activated.

The sensor section 9 is a circuit which measures electric power (i.e., electric power supplied to a load) which is consumed by a load connected to the socket 5. The sensor section 9 includes a shunt resistor 9a and an electric power measuring section 9b (electric power measuring means).

The shunt resistor 9a has a small resistance of, for example, approximately 1 nm. The shunt resistor 9a is connected in series with one of the wires 4a and 4b (e.g., with the wire 4b) so as to be, for example, in the vicinity of the socket 5.

The electric power measuring section 9b measures voltages across the shunt resistor 9a, and measures, based on the voltages thus measured, a current which flows in the shunt resistor 9a (i.e., a current which flows to the socket 5). Moreover, the electric power measuring section 9b measures a voltage across the wires 4a and 4b (i.e., a voltage to be applied to the socket 5). Then, the electric power measuring section 9b carries out a multiplication of the current and voltage thus measured so as to measure the electric power which is consumed by the load connected to the socket 5. Note that the electric power measured by the electric power measuring section 9b does not contain electric power which is consumed by the electric power measuring device 1.

The memory section 11 is configured by, for example, a nonvolatile memory. The memory section 11 stores (i) measurement error information regarding the electric power measuring section 9b and (ii) an electric power value consumed by a predetermined load whose accurate electric power value is known.

The switch 15 accepts user's instructions on various operations which are carried out by the electric power measuring device 1. The switch 15 is configured by, for example, a push key.

When the user's instruction on a corresponding operation is entered via the switch 15, the correcting section 13 corrects, based on the measurement error information stored in the memory section 11, a value of electric power measured by the electric power measuring section 9b.

The communication section 17 (i) converts, into for example an RF signal, the value of measured electric power which has been corrected by the correcting section 13 (hereinafter, the value thus corrected is referred to as electric power information) and then (ii) sends the electric power information to a predetermined information-processing device (e.g., a server) 19.

The information-processing device 19 stores the electric power information sent from the communication section 17. The electric power information stored in the information-processing device 19 can be displayed, when a predetermined operation is carried out with respect to the information-processing device 19, on a predetermined display section which is included in the information-processing device 19. Note that, in a case of storing a plurality of pieces of electric power information of respective of a plurality of electric power measuring devices 1 in the information-processing device 19, a plurality of pieces of electric power information of and a plurality of pieces of identification information of the respective plurality of electric power measuring devices 1 are sent to and stored by the information-processing device 19 so that each of the pieces of electric power information and a corresponding one of the pieces of identification information are associated with each other.

Note here that, according to the present embodiment, a communication between the electric power measuring device 1 and the information-processing device 19 is carried out wirelessly with the use of, for example, an RF signal. Alternatively, such a communication can be carried out with the use of a wire such as an LAN cable.

Note also that, according to the present embodiment, the electric power information is stored in the information-processing device 19. The present embodiment is not limited to this, and the electric power information can therefore be stored in the memory section 11 of the electric power measuring device 1. Alternatively, it is possible for the electric power measuring device 1 to include a display section for displaying electric power information so that the electric power information can be displayed on the display section.

When an instruction on a corresponding operation is entered via the switch 15, the calculating section 21 calculates a difference (=value of measured electric power−electric power value) between (i) a value of electric power measured by the electric power measuring section 9b when the predetermined load is connected to the socket 5 and (ii) the electric power value stored in the memory section 11. Then, the calculating section 21 calculates, based on the difference, measurement error information (=(value of measured electric power−electric power value)/electric power value) of the electric power measuring section 9b, and then stores the measurement error information in the memory section 11. In a case where measurement error information has already been stored in the memory section 11, the measurement error information is overwritten and stored in the memory section 11.

The correcting section 13 corrects a value of measured electric power based on measurement error information. The correction is carried out with the use of, for example, the following arithmetic expression: value of measured electric power/(1+measurement error information).

The switch signal processing section 22 controls, for example, activation/deactivation of the correcting section 13 and the calculating section 21, in response to an instruction on a corresponding operation being entered via the switch 15. More specifically, in a case where, for example, an instruction on a particular operation is entered via the switch 15, the switch signal processing section 22 deactivates the correcting section 13 and activates the calculating section 21 (i.e., the electric power measuring device 1 selects a setting mode of measurement error information). This causes the calculating section 21 to calculate measurement error information and to store, in the memory section 11, the measurement error information thus calculated, as described above.

In a case where the instruction on the particular operation is not entered via the switch 15, the switch signal processing section 22 activates the correcting section 13 and deactivates the calculating section 21 (i.e., the electric power measuring device 1 selects an electric power measuring mode in which electric power consumed by a load, which is connected with the socket 5, is measured). This causes the correcting section 13 to correct, based on measurement error information stored in the memory section 11, a value of electric power measured by the electric power measuring section 9b, and the value thus corrected is sent to the information-processing device 19 via the communication section 17, as described above.

The lamp controlling section 23 (i) detects operation states of the sections such as the correcting section 13, the calculating section 21, and the communication section 17, and (ii) changes a turn-on pattern of the lamp 25 based on a detected result. The turn-on pattern of the lamp 25 allows a current operation state of the electric power measuring device 1 to be informed to the user.

### (Procedure for Setting Measurement Error Information)

The following describes a procedure for setting measurement error information of the electric power measuring device 1 with reference to FIG. 1.

The plug 3 is connected to a predetermined power supply outlet so as to activate the electric power measuring device 1. This causes the correcting section 13 to be activated, while the calculating section 21 remains deactivated, so that the electric power measuring device 1 is entered in an electric power measuring mode. Specifically, the electric power measuring device 1 is automatically entered into the electric power measuring mode when the electric power measuring device 1 starts to operate. Subsequently, the instruction on the particular operation mode of the electric power measuring device 1 is entered via the switch 15 so that the electric power measuring device 1 is changed into a setting mode of measurement error information. This causes the correcting section 13 to be deactivated and the calculating section 21 to be activated.

Then, a predetermined load (i.e., a load having electric power which is identical to an electric power value (e.g., 300 W) stored in the memory section 11) is connected to the socket 5. Then, the electric power measuring section 9b measures electric power consumed by the predetermined load, and the calculating section 21 calculates a difference between a value (e.g., 330 W) of electric power measured by the electric power measuring section 9b and the electric power value (e.g., 300 W) stored in advance in the memory section 11. Based on the difference (i.e., 330 W−300 W=+30 W), measurement error information (=(330 W−300 W)/300 W=+0.1=+10%) of the electric power measuring section 9b is calculated, and then the measurement error information is stored in the memory section 11.

Subsequently, the plug 3 is disconnected from the predetermined power supply outlet, and the predetermined load is disconnected from the socket 5. This is how the measurement error information is set. Note that the setting of measurement error information is carried out, for example, on a side of a company which manufactures electric power measuring devices. A setting of measurement error information is thus carried out only when an instruction on a particular operation is entered via the switch 15. This makes it possible to prevent a user from freely carrying out a setting of measurement error information.

### [Electric Power Measuring Operation of Electric Power Measuring Device 1]

The following describes how the electric power measuring device 1 measures electric power.

A user, for example, connects the plug 3 to a predetermined power supply outlet so as to activate the electric power measuring device 1. This causes the correcting section 13 to be activated, while the calculating section 21 remains deactivated, so that the electric power measuring device 1 is entered into the electric power measuring mode.

Subsequently, a load, whose electric power is to be measured, is connected to the socket 5 by, for example, the user. This causes a measuring of electric power consumed by the load, which is connected with the socket 5, to be started. Specifically, electric power is supplied from the predetermined power supply outlet to the load, via the plug 3, the wires 4a and 4b, and the socket 5. Concurrently, the electric power measuring section 9b measures, for example at predetermined intervals, electric power supplied to the load. Then, the correcting section 13 corrects, based on measurement error information stored in the memory section 11, a value of the electric power measured by the electric power measuring section 9b. In a case where a value of electric power measured by the electric power measuring section 9b is, for example, 660 W, the correcting section 13 corrects the value of measured electric power to be 600 W=value of measured electric power/(1+measurement error information)=660 W/(1+0.1). A corrected value of measured electric power (i.e., electric power information) is sent to a predetermined information-processing device 19 via the communication section 17 and then stored in the information-processing device 19.

According to the electric power measuring device 1, (i) measurement error information is stored in the memory section 11 and (ii) the correcting section 13 corrects, based on the measurement error information, a value of electric power measured by the electric power measuring section 9b. That is, the value of measured electric power is corrected by use of a software-based method, instead of using a conventional hardware-based method. This makes it possible to reduce parts cost and manufacturing cost without deteriorating accuracy in measuring electric power.

The memory section 11 stores an electric power value consumed by a predetermined load, and the calculating section 21 calculates measurement error information based on (i) a value of electric power measured by the electric power measuring section 9b when the predetermined load is connected to the socket and (ii) the electric power value consumed by the predetermined load. This makes it possible to obtain accurate measurement error information in the electric power measuring device 1.

### Embodiment 2

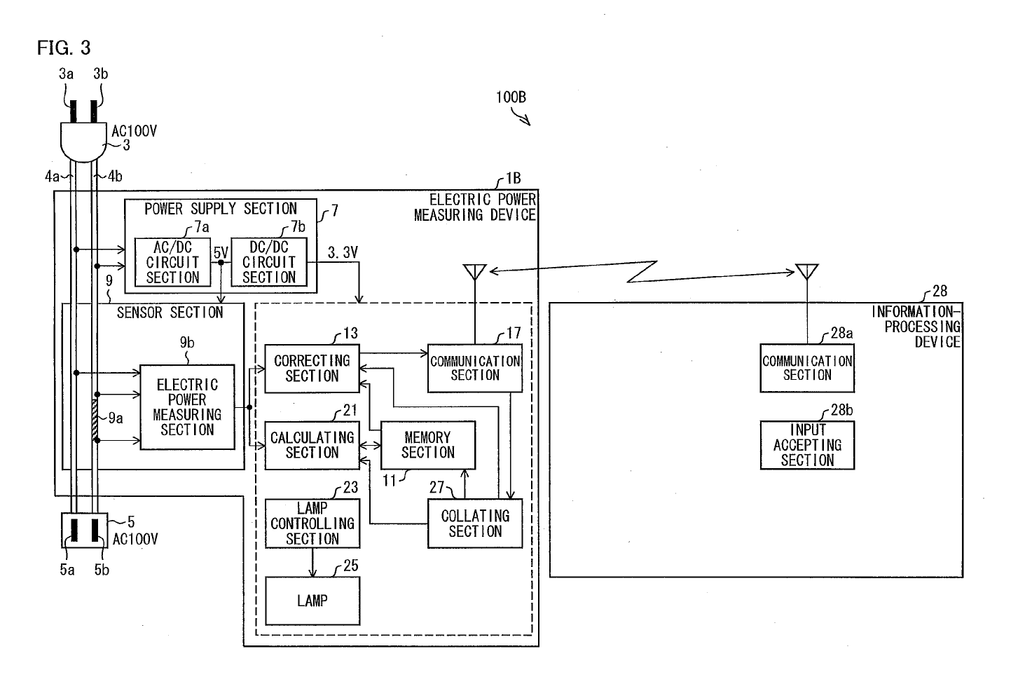

According to Embodiment 1, the setting of measurement error information is carried out in response to an instruction on a particular operation being entered via the switch 15 of the electric power measuring device 1. According to Embodiment 2, a setting of measurement error information in an electric power measuring device 1B is carried out in response to an instruction on a particular operation being given from an external information-processing device 28 (such as a computer or a server) via communication (see FIG. 3).

The following describes an electric power measuring system 100B of the present embodiment with reference to FIG. 3. Note that the same reference numerals are given to constituent members which are identical to those in Embodiment 1, and descriptions of such members are omitted here. The following therefore describes only constituent members which are different from those in Embodiment 1.

The electric power measuring system 100B includes an electric power measuring device 1B and an external information-processing device 28 (a predetermined information-processing device).

The information-processing device 28 includes (i) a communication section 28a (second communication means) via which communication is carried out between a communication section 17 of the electric power measuring device 1B and (ii) an input accepting section 28b (operation accepting means) which receives an operation given by a person.

The input accepting section 28b receives (i) authentication information such as a password and (ii) an instruction on switching the electric power measuring device 1B to a setting mode of measurement error information. When the authentication information and the instruction are entered via the input accepting section 28b, the authentication information and the instruction are sent to the communication section 17 of the electric power measuring device 1B via the communication section 28a.

The electric power measuring device 1B has a configuration substantially identical to that of the electric power measuring device 1 of Embodiment 1, except that the electric power measuring device 1B includes a collating section 27 (collating means) but does not include a switch 15 and a switch signal processing section 22.

In the collating section 27, authentication information (hereinafter, referred to as first authentication information) such as a password or ID information is set in advance. When the collating section receives, via the communication section 17, authentication information (hereinafter, referred to as second authentication information) sent from the information-processing device 28, the collating section 27 carries out a collation of the second authentication information and the first authentication information.

The memory section 11 (memory means) permits writing of measurement error information into the memory section 11 only when the first authentication information and the second authentication information are identical to each other, as a result of the collation carried out by the collating section 27. Therefore, in a case where the first authentication information and the second authentication information are not identical to each other, the measurement error information cannot be written into the memory section 11.

When the collating section 27 receives, via the communication section 17 (first communication means), the instruction sent from the information-processing device 28, the correcting section 13 is deactivated and the calculating section 21 is activated (i.e., the electric power measuring device 1B is switched to the setting mode of measurement error information). This causes the calculating section 21 to calculate measurement error information, as with Embodiment 1. In a case where a writing of measurement error information is permitted by the memory section 11, the measurement error information thus calculated is written into the memory section 11 (i.e., stored in the memory section 11). Whereas, in a case where a writing of measurement error information is not permitted by the memory section 11, the measurement error information thus calculated is not written into the memory section 11 (i.e., not stored in the memory section 11) and is cleared.

According to the electric power measuring system 100B, the following effect can be brought about, in addition to the effects brought about by the configurations which are similar to those in Embodiment 1. That is, according to the electric power measuring device 1B, measurement error information is calculated in response to an instruction which is sent from the information-processing device 28 via the communication section 17. As such, it is possible to set measurement error information in response to an external instruction supplied with the use of the information-processing device 28.

Moreover, the collating section 27 carries out a collation of (i) the second authentication information which is received by the communication section 17 and (ii) the first authentication information which is set in advance. A writing of measurement error information into the memory section 11 is permitted only when the first authentication information and the second authentication information are identical to each other as a result of the collation. Therefore, only a person, who knows the authentication information, can set measurement error information. This makes it possible to prevent a user from freely rewriting the measurement error information.

### Embodiment 3

According to Embodiment 1, the electric power measuring device 1 carries out (i) a calculation of measurement error information, (ii) storage of the measurement error information, and (iii) a correction of a value of measured electric power. According to Embodiment 2, an electric power measuring device 1C carries out a calculation of measurement error information and a correction of a value of measured electric power, and an external information-processing device 29 stores the measurement error information.

### (Outline of Electric Power Measuring System 100C)

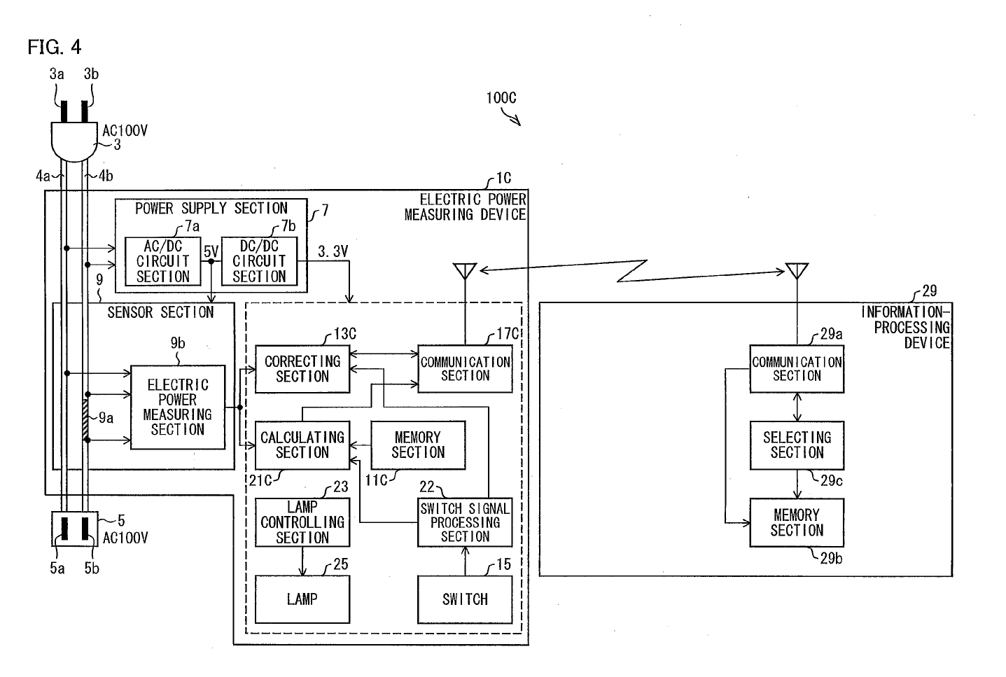

The following describes an electric power measuring system 100C of the present embodiment, with reference to FIG. 4. Note that the same reference numerals are given to constituent members which are identical to those in Embodiment 1, and descriptions of such constituent members are omitted here. The following therefore describes only constituent members which are different from those in Embodiment 1.

The electric power measuring system 100C includes an electric power measuring device 1C and an external information-processing device 29 which stores measurement error information regarding the electric power measuring device 1C.

The electric power measuring device 1C includes a memory section 11C (second memory means) which stores an electric power value consumed by a predetermined load whose accurate electric power value is known but does not store measurement error information regarding an electric power measuring section 9b.

The electric power measuring device 1C includes a calculating section 21C (calculating means) which calculates measurement error information, as with the calculating section 21 of Embodiment 1. The calculating section 21C supplies the measurement error information thus calculated to a communication section 17C (first communication means).

The communication section 17C of the electric power measuring device 1C sends the measurement error information, which is supplied from the calculating section 21C, to the information-processing device 29 together with identification information of the electric power measuring device 1C.

The electric power measuring device 1C includes a correcting section 13C (correcting means) which sends, when the correcting section 13C starts to operate, the identification information of the electric power measuring device 1C to the information-processing device 29 via the communication section 17C. This causes the information-processing device 29 to send measurement error information regarding the electric power measuring section 9b (electric power measuring means) to the electric power measuring device 1C, as later described. When the correcting section 13C receives the measurement error information from the information-processing device 29, via the communication section 17C, the correcting section 13C corrects, based on the measurement error information thus received, a value of electric power measured by the electric power measuring section 9b, as with the correcting section 13 of Embodiment 1.

The other constituent members of the electric power measuring device 1C are configured similarly to the constituent members, to which the same reference numerals are given, of the electric power measuring device 1 in Embodiment 1.

The information-processing device 29 includes a communication section 29a (second communication means), a memory section 29b (first memory means), and a selecting section 29c (selecting means). The information-processing device 29 is provided, for example, in facilities on a manufacturer side.

The communication section 29a carries out communication with the communication section 17C of the electric power measuring device 1C. The memory section 29b is configured by, for example, a nonvolatile memory or a hard disk. The measurement error information and the identification information which are sent from the communication section 17C are stored by memory section 29b so as to be associated with each other.

The memory section 29b stores the identification information and the measurement error information of the electric power measuring device 1C which are sent from the electric power measuring device 1C. Note that, in a case where there are a plurality of electric power measuring devices which communicate with the information-processing device 29, pieces of identification information of the respective plurality of electric power measuring devices and pieces of measurement error information of the respective plurality of electric power measuring devices are stored by the memory section 29b so as to be associated with each other.

When the communication section 29a receives the identification information sent from the electric power measuring device 1C, the selecting section 29c selects a piece of measurement error information (i.e., measurement error information regarding the electric power measuring device 1C), which is associated with the identification information thus received, from pieces of measurement error information stored in the memory section 29b. The piece of measurement error information thus selected is sent to the communication section 17C of the electric power measuring device 1C, via the communication section 29a.

### (Procedure for Setting Measurement Error Information)

The following describes a procedure for setting measurement error information in the electric power measuring system 100C.

First, the calculating section 21C calculates measurement error information in accordance with a procedure similar to that of Embodiment 1. The communication section 17C sends, together with identification information of the electric power measuring device 1C, the measurement error information thus calculated to the communication section 29a of the information-processing device 29. Then, the measurement error information and the identification information are stored in the memory section 29b of the information-processing device 29 so as to be associated with each other. The measurement error information, which is calculated in the electric power measuring device 1C, is stored in the memory section 29b of the information-processing device 29.

### (Electric Power Measuring Operation of Electric Power Measuring Device 1C)

The following describes how the electric power measuring device 1C measures electric power.

First, the electric power measuring device 1C is activated in a procedure similar to that of Embodiment 1. This causes the correcting section 13C to start to operate, and identification information of the electric power measuring device 1C is sent to the communication section 29a of the information-processing device 29, via the communication section 17C.

The information-processing device 29 receives, via the communication section 29a, the identification information sent from the communication section 17. Then, the selecting section 29c selects a piece of measurement error information (i.e., measurement error information regarding the electric power measuring device 1C), which is associated with the identification information received by the communication section 29a, from pieces of measurement error information stored in the memory section 29b. The piece of measurement error information thus selected is sent to the communication section 17C of the electric power measuring device 1C, via the communication section 29a.

The communication section 17C of the electric power measuring device 1C receives the piece of measurement error information sent from the communication section 29a. Then, the correcting section 13C corrects, as with Embodiment 1, a value of electric power measured by the electric power measuring section 9b with the use of the piece of measurement error information thus received. The value of measured electric power thus corrected (i.e., electric power information) is sent to a predetermined information-processing device (not illustrated) by the communication section 17C and stored in the predetermined information-processing device, as with Embodiment 1.

According to the electric power measuring system 100C, the following effect can be brought about, in addition to the effects brought about by the configurations which are similar to those in Embodiment 1. That is, the measurement error information is received from the information-processing device 29 via the communication section 17C (i.e., the measurement error information is not stored in the electric power measuring device 1C). This makes it possible to reduce memory capacity for storing measurement error information in the electric power measuring device 1C, and therefore parts cost of the electric power measuring device 1C can be reduced.

Moreover, (i) the pieces of measurement error information and pieces of identification information which are stored in the memory section 29b so as to be associated with each other, (ii) the selecting section 29c selects a piece of measurement error information, which is associated with identification information identical to that received by the communication section 29a, from the pieces of measurement error information stored in the memory section 29b, and (iii) the communication section 29a sends the piece of measurement error information thus selected to the electric power measuring device 1C. This allows pieces of measurement error information of respective of a plurality of electric power measuring devices 1C to be stored in the memory section 29b without confusion.

### Embodiment 4

According to Embodiment 3, the electric power measuring device 1C carries out the calculation of measurement error information and the correction of a value of measured electric power, and the measurement error information is stored in the external information-processing device 29. According to Embodiment 4, an electric power measuring device 1D carries out a correction of measured electric power, and an external information-processing device 29D carries out (i) a calculation of measurement error information and (ii) storage of the measurement error information.

### (Outline of Electric Power Measuring System 100D)

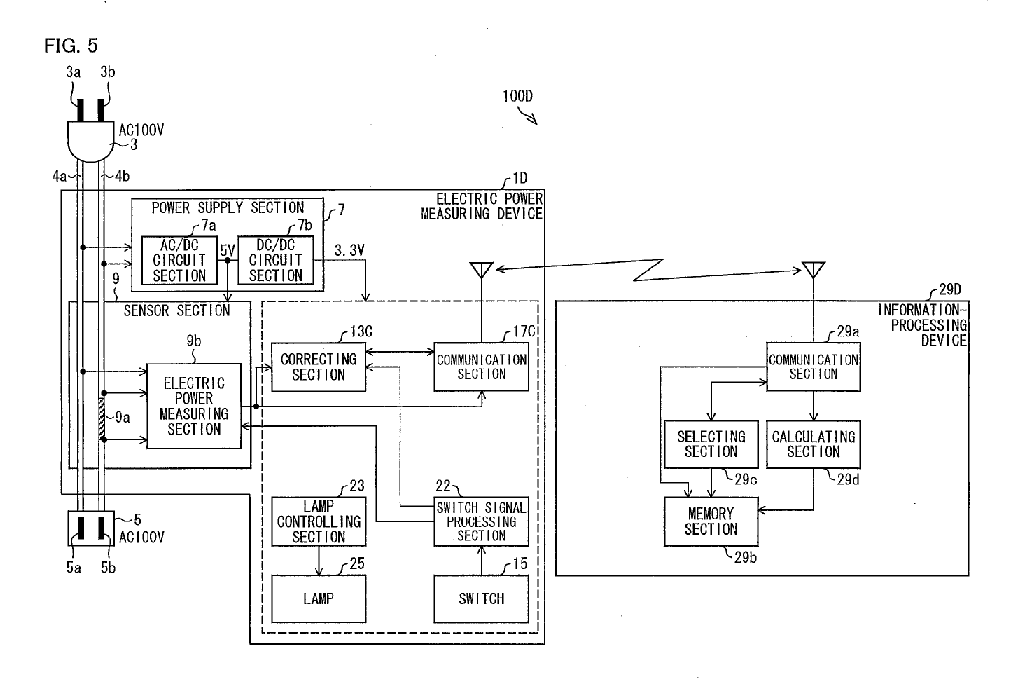

The following describes an electric power measuring system 100D of the present embodiment, with reference to FIG. 5. Note that the same reference numerals are given to constituent members which are identical to those in Embodiment 3, and descriptions of such constituent members are omitted here. The following therefore describes only constituent members which are different from those in Embodiment 3.

The electric power measuring device 1D of the present embodiment has a configuration substantially identical to that of the electric power measuring device 1C of Embodiment 3, except that the electric power measuring device 1D does not include (i) a calculating section 21C which calculates measurement error information and (ii) a memory section 11C which stores an electric power value used in calculating the measurement error information.

An electric power measuring section 9b of the electric power measuring device 1D operates, in an electric power measuring mode, in a manner similar to the electric power measuring section 9b of Embodiment 3. On the other hand, in a setting mode of measurement error information, a value of measured electric power (i.e., a value of electric power measured when a predetermined load is connected to the socket 5) is sent, together with identification information of the electric power measuring device 1D, to a communication section 29a of an information-processing device 29D.

The other constituent members of the electric power measuring device 1D are configured similarly to those, to which the same reference numerals are given, of the electric power measuring device 1C in Embodiment 3.

The information-processing device 29D of Embodiment 4 has a configuration which is different from that of Embodiment 3 in that a calculating section 29d, which calculates measurement error information, is further provided. A memory section 29b of the information-processing device 29D stores an electric power value consumed by a predetermined load whose accurate electric power value is known.

When the calculating section 29d receives, via the communication section 29a, the value of measured electric power sent via the communication section 17C, the calculating section 29d (i) calculates a difference between the value of measured electric power and the electric power value stored in the memory section 29b and (ii) calculates measurement error information in a manner similar to the calculating section 21 of Embodiment 1. Subsequently, the measurement error information thus calculated by the calculating section 29d is stored in the memory section 29b so as to be associated with the identification information which is received together with the value of measured electric power.

The other constituent members of the information-processing device 29D are configured similarly to those, to which the same reference numerals are given, of the information-processing device 29 in Embodiment 3.

### (Procedure for Setting Measurement Error Information)

The following describes a procedure for setting measurement error information in the electric power measuring system 100D.

The electric power measuring device 1D is activated in a manner similar to Embodiment 1. Then, an instruction on a particular operation is entered via a switch 15 so that a setting mode of measurement error information is selected. Subsequently, a predetermined load (i.e., a load having an electric power value which is identical to that stored in the memory section 29b) is connected to the socket 5. This causes the electric power measuring section 9b to measure electric power consumed by the predetermined load, and a value of the measured electric power is sent, together with identification information of the electric power measuring device 1D, to the communication section 29a of the information-processing device 29D, via the communication section 17C.

The information-processing device 29D receives, via the communication section 29a, the value of measured electric power and the identification information which are sent from the communication section 17C. Then, the calculating section 29d calculates (i) a difference between the value of the measured electric power received by the communication section 29a and the electric power value stored in advance in the memory section 29b and (ii) measurement error information in a manner similar to the calculating section 21 of Embodiment 1. The measurement error information thus calculated by the calculating section 29d is stored in the memory section 29b so as to be associated with the identification information which is received via the communication section 29a together with the value of measured electric power. This is how the measurement error information is set.

Note that how the electric power measuring system 100D carries out an electric power measuring operation is identical to that of Embodiment 3, and therefore descriptions of the electric power measuring operation is omitted here.

According to the electric power measuring system 100D, the following effect can be brought about, in addition to the effects brought about by the configurations which are similar to those in Embodiment 3. That is, according to the electric power measuring device 1D, the information-processing device 29D receives, via the communication section 17C, the value of electric power measured by the electric power measuring section 9b when the predetermined load is connected to the socket 5. According to the information-processing device 29D, (i) the electric power value consumed by the predetermined load is stored in the memory section 29b and (ii) the calculating section 29d calculates measurement error information based on the value of measured electric power and the electric power value. This makes it possible to accurately calculate, in an information-processing device, measurement error information regarding an electric power measuring device.

Moreover, measurement error information is calculated by the information-processing device 29D (i.e., measurement error information is not calculated by the electric power measuring device 1D), and therefore a processing load on the electric power measuring device 1D can be reduced.

### Embodiment 5

According to Embodiment 4, a value of measured electric power is corrected in the electric power measuring device 1D, and measurement error information is calculated and stored in the information-processing device 29D. According to Embodiment 5, an information-processing device 29E calculates and stores measurement error information, and corrects a value of measured electric power.

### (Outline of Electric Power Measuring System 100E)

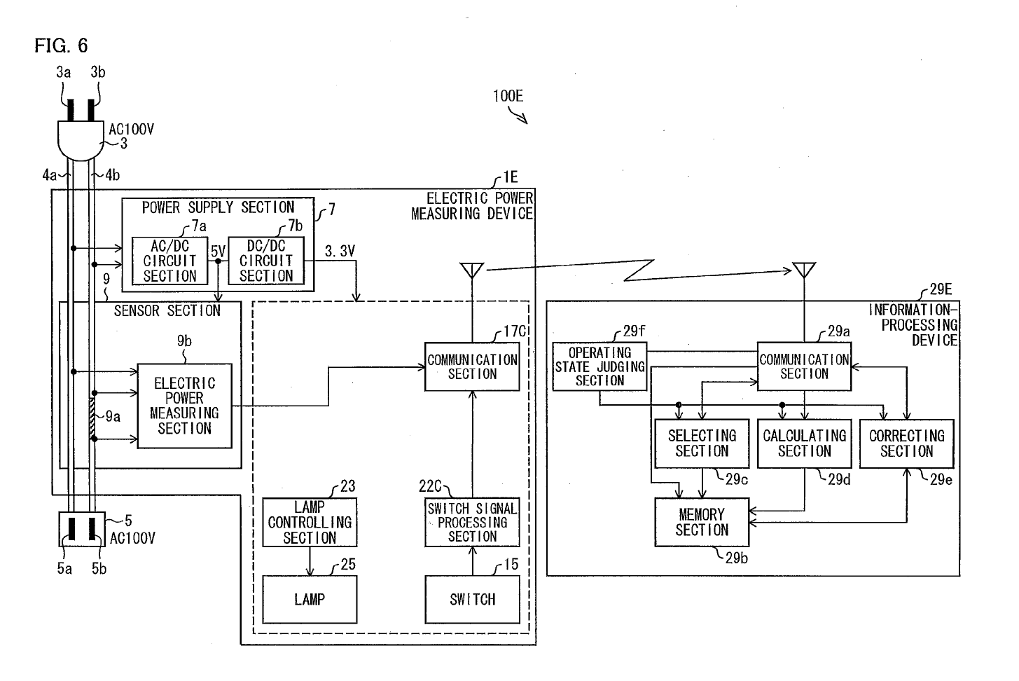

The following describes an electric power measuring system 100E of the present embodiment, with reference to FIG. 6. Note that the same reference numerals are given to constituent members which are identical to those in Embodiment 4, and descriptions of such constituent members are omitted here. The following therefore describes only constituent members which are different from those in Embodiment 4.

The electric power measuring device 1E of the present embodiment has a configuration substantially identical to that of the electric power measuring device 1D of Embodiment 4, except that no correcting section 13C, which corrects a value of measured electric power, is provided.

The electric power measuring device 1E includes an electric power measuring section 9b which outputs a value of measured electric power via a communication section 17C.

When an instruction on a particular operation is not entered via a switch 15, a switch signal processing section 22C of the electric power measuring device 1E outputs, via the communication section 17C, information (hereinafter, referred to as operation state information) indicating that the electric power measuring device 1E is in an electric power measuring mode. Whereas, when such an instruction on the particular operation is entered via the switch 15, the switch signal processing section 22C outputs, via the communication section 17C, operation state information indicating that the electric power measuring device 1E is in a setting mode of measurement error information.

When the communication section 17C of the electric power measuring device 1E receives the value of measured electric power from the electric power measuring section 9b, the communication section 17C sends, to a communication section 29a of the information-processing device 29E, the value of measured electric power together with identification information of the electric power measuring device 1E and operation state information supplied from the switch signal processing section 22C.

The other constituent members of the electric power measuring device 1E are configured similarly to those, to which the same reference numerals are given, of the electric power measuring device 1D in Embodiment 4.

The information-processing device 29E of the present embodiment has a configuration substantially identical to that of the information-processing device 29D of Embodiment 4, except that the information-processing device 29E further includes (i) a correcting section 29e which corrects a value of measured electric power and (ii) an operating state judging section 29f.

When the communication section 29a receives the value of measured electric power, the identification information, and the operation state information, the operating state judging section 29f judges, based on the operation state information, whether the electric power measuring device 1E is in the setting mode of measurement error information or in the electric power measuring mode.

Note that, when the electric power measuring device 1E is judged to be in the setting mode of measurement error information, the calculating section 29d calculates, based on the value of measured electric power received via the communication section 29a, measurement error information in a manner similar to Embodiment 4 (i.e., similar to Embodiment 3). The measurement error information thus calculated is stored in the memory section 29b. Whereas, when the electric power measuring device 1E is judged to be in the electric power measuring mode, the value of measured electric power is corrected with the use of the correcting section 29e and the selecting section 29c.

When the electric power measuring device 1E is judged, by the operating state judging section 29f, to be in the electric power measuring mode, the selecting section 29c of the present embodiment selects, in a manner similar to Embodiment 4 (i.e., in a manner similar to Embodiment 3), a piece of measurement error information (i.e., measurement error information regarding the electric power measuring device 1E), which is associated with the identification information received by the communication section 29a, from pieces of measurement error information stored in the memory section 29b. The piece of measurement error information thus selected is supplied to the correcting section 29e.

Moreover, when the electric power measuring device 1E is judged, by the operating state judging section 29f, to be in the electric power measuring mode, the correcting section 29e of the present embodiment corrects, in a manner similar to Embodiment 4 (i.e., in a manner similar to Embodiment 1), the value of measured electric power, which is received by the communication section 29a, with the use of the piece of measurement error information selected by the selecting section 29c. The value of measured electric power thus corrected (i.e., electric power information) by the correcting section 29e is (i) sent to a predetermined server via the communication section 29a and (ii) stored in the predetermined server, as with Embodiment 4.

The other constituent members of the information-processing device 29E are configured similarly to those, to which the same reference numerals are given, of the information-processing device 29 in Embodiment 3.

### (Procedure for Setting Measurement Error Information)

The following describes a procedure for setting measurement error information in the electric power measuring system 100E.

The electric power measuring device 1E is activated by connecting a plug 3 to a predetermined power supply outlet. Then, an instruction on a particular operation is entered via the switch 15 so that the setting mode of measurement error information is selected. Subsequently, a predetermined load (i.e., a load having an electric power value which is identical to an electric power value stored in the memory section 29b) is connected to the socket 5. This causes the electric power measuring section 9b to measure electric power consumed by the predetermined load, and a value of the measured electric power is sent, together with identification information of the electric power measuring device 1E and operation state information indicating that the electric power measuring device 1E is in the setting mode of measurement error information, to the communication section 29a of the information-processing device 29E, via the communication section 17C.

Then, the information-processing device 29E receives, via the communication section 29a, the value of measured electric power, the identification information, and the operation state information sent via the communication section 17C.

Based on the operation state information received via the communication section 29a, the electric power measuring device 1E is judged, by the operating state judging section 29f, to be in the electric power measuring mode. In accordance with a judged result, the calculating section 29d calculates, in a manner similar to Embodiment 4, measurement error information based on the value of measured electric power received via the communication section 29a. The measurement error information thus calculated is stored in the memory section 29b so as to be associated with the identification information received by the communication section 29a. This is how the measurement error information is set.

### (Electric Power Measuring Operation in Electric Power Measuring System 100E)

The following describes how electric power is measured by the electric power measuring system 100E. First, the electric power measuring device 1E is activated in a procedure similar to that described above (i.e., the electric power measuring device 1E is automatically entered into the electric power measuring mode). Then, a load, whose electric power is to be measured, is connected to the socket 5. This causes the electric power measuring section 9b to start measuring electric power consumed by the load connected to the socket 5. A value of the measured electric power is sent, together with identification information of the electric power measuring device 1E and operation state information indicating that the electric power measuring device 1E is in the electric power measuring mode, to the communication section 29a of the information-processing device 29E via the communication section 17C.

Then, the information-processing device 29E receives, via the communication section 29a, the value of measured electric power, the identification information, and the operation state information sent via the communication section 17C. Based on the operation state information received via the communication section 29a, the electric power measuring device 1E is judged, by the operating state judging section 29f, to be in the electric power measuring mode. The value of measured electric power received via the communication section 29a is corrected, in accordance with a judged result, with the use of the selecting section 29c and the correcting section 29e.

Specifically, the selecting section 29c selects a piece of measurement error information (i.e., measurement error information regarding the electric power measuring device 1E), which is associated with the identification information received by the communication section 29a, from pieces of measurement error information stored in the memory section 29b. The piece of measurement error information thus selected is supplied to the correcting section 29e. Then, the correcting section 29e corrects, with the use of the piece of measurement error information selected by the selecting section 29c, the value of measured electric power received via the communication section 17C.

The value of measured electric power thus corrected (i.e., electric power information) is sent to a predetermined information-processing device (not illustrated) via the communication section 29a and stored in the predetermined information-processing device, as with Embodiment 1. Note that the electric power information can be stored in the memory section 29b instead of in the predetermined information-processing device. This is how electric power consumed by the load is measured.

According to the electric power measuring system 100E, the following effect can be brought about, in addition to the effects brought about by the configurations which are similar to those in Embodiment 4. That is, according to the electric power measuring device 1E, the value of electric power measured by the electric power measuring section 9b is sent to the information-processing device 29E via the communication section 17C. According to the information-processing device 29E, (i) measurement error information is stored in the memory section 29b, and (ii) the correcting section 29e corrects, based on the measurement error information, the value of electric power measured by the electric power measuring section 9b. That is, the value of measured electric power is corrected by the use of a software-based method, instead of using a conventional hardware-based method. This makes it possible to reduce parts cost and manufacturing cost without deteriorating accuracy in measuring electric power.

Moreover, according to the electric power measuring device 1E, the value of measured electric power and the identification information are sent via the communication section 17C to the information-processing device 29E. According to the information-processing device 29E, (i) the measurement error information and the identification information are stored in the memory section 29b so as to be associated with each other, and (ii) the correcting section 29e corrects the value of measured electric power, sent from the electric power measuring device 1E, with the use of measurement error information which is associated with identification information identical to the identification information sent from the electric power measuring device 1E. This allows the information-processing device 29E to correct, without confusion, values of electric power measured by respective of a plurality of electric power measuring devices 1E.

Moreover, the correction of the value of measured electric power is carried out by the information-processing device 29E, and therefore a processing load on the electric power measuring device 1E can be reduced.

### (Additional Remarks)

Note that each of the embodiments encompasses a measuring method with the use of the electric power measuring device.

The present invention is not limited to the embodiments, but can be altered by a skilled person in the art within the scope of the claims. An embodiment derived from a proper combination of technical means disclosed in respective different embodiments is also encompassed in the technical scope of the present invention.

Lastly, the electric power measuring devices 1, 1B, 1C, 1D, and 1E and the information-processing devices 19, 28, 29, 29D, and 29E, in particular, the electric power measuring section 9b, the memory sections 11, 11C, and 29b, the correcting sections 13, 13C, and 29e, the communication sections 17, 17C, and 29a, the calculating sections 21, 21C, and 29d, the lamp controlling section 23, the selecting section 29c, and the operating state judging section 29f, each can be configured by hardware logic or realized by software with the use of CPU as follows.

That is, each of the electric power measuring devices 1, 1B, 1C, 1D, and 1E and the information-processing devices 19, 28, 29, 29D, and 29E includes a CPU, a ROM, a RAM, and a memory device (memory medium) such as a memory. The CPU executes instructions of control programs for realizing the functions of the respective above devices. In the ROM, the programs are stored. Into the RAM the programs are loaded. In the memory device, the programs and various data are stored. The objective of the present invention can also be achieved, by (i) supplying a storage medium, in which program codes (executable programs, intermediate code programs, source programs) of programs for controlling the electric power measuring devices 1, 1B, 1C, 1D, and 1E and the information-processing devices 19, 28, 29, 29D, and 29E, each being configured by software for realizing the functions, are stored so that a computer can read them, to the above devices, and then (ii) causing the computer (or CPU or MPU) to read and execute the program codes stored in the storage medium.

The storage medium can be, for example, a tape, such as a magnetic tape or a cassette tape; a disk including (i) a magnetic disk such as a floppy (Registered Trademark) disk or a hard disk and (ii) an optical disk such as CD-ROM, MO, MD, DVD, or CD-R; a card such as an IC card (memory card) or an optical card; or a semiconductor memory such as a mask ROM, EPROM, EEPROM, or flash ROM.

Alternatively, (i) the electric power measuring devices 1, 1B, 1C, 1D, and 1E and the information-processing devices 19, 28, 29, 29D, and 29E can be arranged to be connected to a communications network so that the program codes are delivered over the communications network. The communications network is not limited to a specific one, and therefore can be, for example, the Internet, an intranet, extranet, LAN, ISDN, VAN, CATV communications network, virtual private network, telephone line network, mobile communications network, or satellite communications network. The transfer medium which constitutes the communications network is not limited to a specific one, and therefore can be, for example, wired line such as IEEE 1394, USB, electric power line, cable TV line, telephone line, or ADSL line; or wireless such as infrared radiation (IrDA, remote control), Bluetooth (Registered Trademark), 802.11 wireless, HDR, mobile telephone network, satellite line, or terrestrial digital network. Note that, the present invention can be realized by a computer data signal (i) which is realized by electronic transmission of the program code and (ii) which is embedded in a carrier wave.

It is preferable that the electric power measuring device of the present invention further includes calculating means for calculating the measurement error information based on (i) a value of electric power measured by the electric power measuring means when a predetermined load is connected with the socket and (ii) an electric power value of the predetermined load, the electric power value being stored in the memory means.

According to the configuration, the electric power value consumed by the predetermined load is stored in the memory means, and the calculating means calculates the measurement error information based on (i) the value of electric power measured by the electric power measuring means when the predetermined load is connected with the socket and (ii) the electric power value. This makes it possible to obtain accurate measurement error information in the electric power measuring device.

It is preferable that the electric power measuring device of the present invention further includes operation accepting means for accepting an instruction on an operation entered by a person, the calculating means calculating the measurement error information in response to an instruction on a particular operation entered via the operation accepting means.

According to the configuration, the measurement error information is calculated in response to the instruction on the particular operation entered via the operation accepting means. This allows the measurement error information to be set by only a person who knows details of the particular operation. This makes it possible to prevent a user from freely rewriting the measurement error information.

It is preferable that the electric power measuring device of the present invention further includes first communication means for communicating with a predetermined information-processing device, the calculating means calculating the measurement error information in response to an instruction supplied from the predetermined information-processing device via the first communication means.

According to the configuration, the measurement error information is calculated in response to the instruction supplied from the predetermined information-processing device via the first communication means. This makes it possible to set measurement error information in response to an instruction which is externally sent with the use of the predetermined information-processing device.

It is preferable that the electric power measuring device of the present invention further includes collating means for carrying out a collation of (i) first authentication information which is received by the first communication means and (ii) second authentication information which is set in advance; the memory means permitting writing of measurement error information into the memory means only when the first authentication information and the second authentication information are identical to each other as a result of the collation carried out by the collating means.

According to the configuration, the collating means carries out a collation of (i) the first authentication information, which is received by the first communication means, and (ii) the second authentication information which is set in advance, and the writing of measurement error information into the memory means is permitted only when the first authentication information and the second authentication information are identical to each other as a result of the collation carried out by the collating means. Therefore, only a person, who knows the authentication information, can set the measurement error information. This makes it possible to prevent a user from freely rewriting the measurement error information.

It is preferable that an electric power measuring system includes: the electric power measuring device; and an information-processing device which can communicate with the electric power measuring device, the first communication means sending identification information of the electric power measuring device to the information-processing device, the information-processing device including: first memory means for storing the measurement error information regarding the electric power measuring means and the identification information of the electric power measuring device so that the measurement error information and the identification information are associated with each other, second communication means for receiving the identification information from the first communication means, and selecting means for selecting the measurement error information which is associated with the identification information received by the second communication means, the second communication means sending the measurement error information, which is selected by the selecting means, to the first communication means.

According to the configuration, the first memory means of the information-processing device stores the measurement error information. This makes it possible to reduce memory capacity for storing measurement error information in the electric power measuring device, and therefore parts cost of the electric power measuring device can be reduced.

Moreover, (i) measurement error information and identification information are stored in the first memory means of the information-processing device so as to be associated with each other, (ii) the selecting means selects a piece of measurement error information, which is associated with the identification information received by the second communication means, from pieces of measurement error information stored in the first memory means, and (iii) the second communication means sends the piece of measurement error information thus selected to the electric power measuring device. This causes the first memory means to store pieces of measurement error information of respective of a plurality of electric power measuring devices without confusion.

According to the electric power measuring system of the present invention, it is preferable that the electric power measuring device further includes: second memory means for storing an electric power value of a predetermined load, and calculating means for calculating the measurement error information based on (i) a value of electric power measured by the electric power measuring means when the predetermined load is connected with the socket and (ii) the electric power value stored in the second memory means, the first communication means sending the measurement error information and identification information of the electric power measuring device to the information-processing device, and the measurement error information and the identification information being stored in the first memory means so as to be associated with each other.

According to the configuration, in the electric power measuring device, the electric power value of the predetermined load is stored in the second memory means, and the calculating means calculates the measurement error information based on (i) the value of electric power measured by the electric power measuring means when the predetermined load is connected with the socket and (ii) the electric power value. This makes it possible to obtain accurate measurement error information in the electric power measuring device.

Moreover, the first communication means of the electric power measuring device sends the measurement error information thus calculated and the identification information of the electric power measuring device to the information-processing device, and the measurement error information and the identification information are stored in the first memory means of the information-processing device so as to be associated with each other. This causes the information-processing device to store pieces of measurement error information of respective of a plurality of electric power measuring devices without confusion.

According to the electric power measuring system of the present invention, it is preferable that the first communication means sends, to the second communication means, a value of electric power measured by the electric power measuring means when a predetermined load is connected with the socket, the information-processing device including: memory means for storing an electric power value of the predetermined load, and calculating means for calculating the measurement error information based on (i) the electric power value stored in the memory means and (ii) the value of measured electric power received via the second communication means.

According to the configuration, in the electric power measuring device, the first communication means sends, to the information-processing device, the value of electric power measured by the electric power measuring means when the predetermined load is connected with the socket. In the information-processing device, the memory means stores the electric power value of the predetermined load, and the calculating means calculates the measurement error information based on the value of measured electric power and the electric power value. This makes it possible to accurately calculate, in the information-processing device, measurement error information regarding the electric power measuring device.

Moreover, the measurement error information is calculated in information-processing device (i.e., the measurement error information is not calculated in the electric power measuring device), and therefore a processing load on the electric power measuring device can be reduced.

It is preferable that the information-processing device of the present invention further includes calculating means for calculating the measurement error information based on (i) an electric power value of a predetermined load, the electric power value being stored in the memory means, and (ii) the value of measured electric power received via the communication means, the value of measured electric power being obtained by measuring electric power consumed by the predetermined load.

According to the configuration of the information-processing device, (a) the memory means stores the electric power value of the predetermined load, (b) the calculating means calculates the measurement error information based on (i) the electric power value and (ii) the value of the measured electric power, which corresponds to the predetermined load, received via the communication means. This makes it possible to obtain accurate measurement error information in the information-processing device.

Note that each of the electric power measuring device, the electric power measuring system, and the information-processing device can be realized by a computer. In such a case, the present invention encompasses (i) a control program which causes a computer to serve as the means of the electric power measuring device or the electric power measuring system so that the electric power measuring device or the electric power measuring system can be realized by the computer and (ii) a non-transitory computer-readable storage medium which stores the control program.

### INDUSTRIAL APPLICABILITY

The present invention can be used as a device for measuring power consumption of a household appliance in a home or of an office appliance in an office.

### REFERENCE SIGNS LIST

1, 1B, 1C, 1D, and 1E: Electric power measuring device
3: Plug
4a and 4b: Wire
5: Socket
7: Power supply section
9: Sensor section
9a: Shunt resistor
9b: Electric power measuring section (electric power measuring means)
11: Memory section (memory means)
11C: Memory section (second memory means)
13, 13C, and 29e: Correcting section (correcting means)
15: Switch (operation accepting means)
17 and 17C: Communication section (first communication means)
19, 28, 29, 29D, and 29E: Information-processing device
21, 21C, and 29d: Calculating section (calculating means)
23: Lamp controlling section
27: Collating section (collating means)
29a: Communication section (second communication means)
29b: Memory section (first memory means)
29c: Selecting section (selecting means)
29f: Operating state judging section
100B, 100C, 100D, and 100E: Electric power measuring system

1. An electric power measuring device comprising:
a plug which is to be connected to a power supply outlet;
a socket to which a load is connected so that electric power is supplied from the plug to the load;
electric power measuring means for measuring the electric power which is supplied to the load;
memory means for storing measurement error information regarding the electric power measuring means; and
correcting means for correcting, based on the measurement error information, a value of electric power measured by the electric power measuring means.

2. An electric power measuring device as set forth in claim 1, further comprising:
calculating means for calculating the measurement error information based on (i) a value of electric power measured by the electric power measuring means when a predetermined load is connected with the socket and (ii) an electric power value of the predetermined load, the electric power value being stored in the memory means.

3. An electric power measuring device as set forth in claim 2, further comprising:
operation accepting means for accepting an instruction on an operation entered by a person,
the calculating means calculating the measurement error information in response to an instruction on a particular operation entered via the operation accepting means.

4. An electric power measuring device as set forth in claim 2, further comprising:
first communication means for communicating with a predetermined information-processing device,
the calculating means calculating the measurement error information in response to an instruction supplied from the predetermined information-processing device via the first communication means.

5. An electric power measuring device as set forth in claim 4, further comprising:
collating means for carrying out a collation of (i) first authentication information which is received by the first communication means and (ii) second authentication information which is set in advance;
the memory means permitting writing of measurement error information into the memory means only when the first authentication information and the second authentication information are identical to each other as a result of the collation carried out by the collating means.

6. An electric power measuring device comprising:
a plug which is to be connected to a power supply outlet;
a socket to which a load is connected so that electric power is supplied from the plug to the load;
electric power measuring means for measuring the electric power which is supplied to the load;
first communication means for receiving measurement error information, which is sent from a predetermined information-processing device, regarding the electric power measuring means; and
correcting means for correcting, based on the measurement error information, a value of electric power measured by the electric power measuring means.

7. An electric power measuring system comprising:
an electric power measuring device recited in claim 6; and
an information-processing device which can communicate with the electric power measuring device,
the first communication means sending identification information of the electric power measuring device to the information-processing device,
the information-processing device including:
first memory means for storing the measurement error information regarding the electric power measuring means and the identification information of the electric power measuring device so that the measurement error information and the identification information are associated with each other,
second communication means for receiving the identification information from the first communication means, and
selecting means for selecting the measurement error information which is associated with the identification information received by the second communication means,
the second communication means sending the measurement error information, which is selected by the selecting means, to the first communication means.

8. An electric power measuring system comprising:
an electric power measuring device which measures electric power which is consumed by a load; and
an information-processing device which can communicate with the electric power measuring device,
the electric power measuring device including:
a plug which is to be connected to a power supply outlet,
a socket to which the load is connected so that electric power is supplied from the plug to the load,
electric power measuring means for measuring the electric power which is supplied to the load, and
first communication means for sending, to the information-processing device, a value of electric power measured by the electric power measuring means and identification information of the electric power measuring device,
the information-processing device including:
first memory means for storing (i) measurement error information regarding the electric power measuring means and (ii) identification information of the electric power measuring device so that the measurement error information and the identification information are associated with each other,
second communication means for receiving the value of measured electric power and the identification information which are sent via the first communication means,
selecting means for selecting the measurement error information which is associated with the identification information received via the second communication means, and
correcting means for correcting, based on the measurement error information selected by the selecting means, the value of measured electric power received via the second communication means.

9. The electric power measuring system as set forth in claim 7, wherein,
the electric power measuring device further includes:
second memory means for storing an electric power value of a predetermined load, and
calculating means for calculating the measurement error information based on (i) a value of electric power measured by the electric power measuring means when the predetermined load is connected with the socket and (ii) the electric power value stored in the second memory means,
the first communication means sending the measurement error information and identification information of the electric power measuring device to the information-processing device, and the measurement error information and the identification information being stored in the first memory means so as to be associated with each other.

10. The electric power measuring system as set forth in claim 8, wherein,
the electric power measuring device further includes:
second memory means for storing an electric power value of a predetermined load, and
calculating means for calculating the measurement error information based on (i) a value of electric power measured by the electric power measuring means when the predetermined load is connected with the socket and (ii) the electric power value stored in the second memory means,
the first communication means sending the measurement error information and identification information of the electric power measuring device to the information-processing device, and the measurement error information and the identification information being stored in the first memory means so as to be associated with each other.

11. The electric power measuring system as set forth in claim 7, wherein:
the first communication means sends, to the second communication means, a value of electric power measured by the electric power measuring means when a predetermined load is connected with the socket,
the information-processing device including:
memory means for storing an electric power value of the predetermined load, and
calculating means for calculating the measurement error information based on (i) the electric power value stored in the memory means and (ii) the value of measured electric power received via the second communication means.

12. The electric power measuring system as set forth in claim 8, wherein:
the first communication means sends, to the second communication means, a value of electric power measured by the electric power measuring means when a predetermined load is connected with the socket,
the information-processing device including:
memory means for storing an electric power value of the predetermined load, and
calculating means for calculating the measurement error information based on (i) the electric power value stored in the memory means and (ii) the value of measured electric power received via the second communication means.

13. An information-processing device, comprising:
memory means for storing (i) measurement error information regarding a predetermined electric power measuring device and (ii) identification information of the predetermined electric power measuring device so that the measurement error information and the identification information are associated with each other;
communication means for receiving, from the predetermined electric power measuring device, a value of measured electric power and identification information;
selecting means for selecting the measurement error information which is associated with the identification information received via the communication means; and
correcting means for correcting, based on the measurement error information selected by the selecting means, the value of measured electric power received via the communication means.

14. The information-processing device as set forth in claim 13, further comprising:
calculating means for calculating the measurement error information based on (i) an electric power value of a predetermined load, the electric power value being stored in the memory means, and (ii) the value of measured electric power received via the communication means, the value of measured electric power being obtained by measuring electric power consumed by the predetermined load.

15. A control program by which an electric power measuring device recited in claim 1 is operated, said control program causing a computer to serve as the means of the electric power measuring device.

16. A control program by which an electric power measuring system recited in claim 7 is operated, said control program causing a computer to serve as the means of the electric power measuring system.

17. A control program by which an information-processing device recited in claim 13 is operated, said control program causing a computer to serve as the means of the information-processing device.

18. A non-transitory computer-readable storage medium in which a control program recited in claim 15 is stored.

19. A non-transitory computer-readable storage medium storing a control program recited in claim 16.

20. A non-transitory computer-readable storage medium storing a control program recited in claim 17.
